(19) United States
(12) Patent Application Publication
(10) Pub. No.: US 2007/0090488 A1
(43) Pub. Date: Apr. 26, 2007

(54) High-efficiency matrix-type LED device

(75) Inventors: Chi-Jen Teng, Miaulih (TW); Wen-Long Chou, Miaulih (TW); Kuo-Jui Huang, Miaulih (TW)

Correspondence Address: TROXELL LAW OFFICE PLLC, SUITE 1404, 5205 LEESBURG PIKE, FALLS CHURCH, VA, 22041, US

(73) Assignee: TYNTEK CORPORATION

(21) Appl. No.: 11/256,070

(22) Filed: Oct. 24, 2005

(51) Int. Cl. H01L 29/861

(52) U.S. Cl. 257/603

(57) ABSTRACT

A high-efficiency matrix-type LED device comprises an epitaxial wafer on which a plurality of independently insulated LEDs are formed by a method of manufacturing integrated circuits; and a conducting line mounted on each one of the LEDs by an evaporation method for forming a large-sized matrix-type LED unit capable of increasing brightness, simplifying manufacturing procedure, and saving manufacturing cost effectively. In addition, a sub-mount having a two-way Zener diode embedded therein is applied to the matrix-type LED unit. By mounting the matrix-type LED unit on the sub-mount, the two-way Zener diode can protect the LEDs against damage from electrostatic discharge (ESD) so as to increase lifetime of LEDs.

### FIELD OF THE INVENTION

The present invention relates to a high-efficiency matrix-type LED (light emitting diode) device or the like capable of simplifying manufacturing procedure, saving manufacturing cost, and increasing brightness.

### BACKGROUND OF THE INVENTION

As disclosed in U.S. Pat. No. 6,472,688 and TW Pat. No. 223,889, a plurality of LEDs are connected with one another in series, parallel, or a mixture of parallel and series for increasing brightness of LEDs. In these patents, it is necessary to mount a single LED on a general sub-mount or PCB and then perform wire-bonding process for connection. Alternatively, each single LED is inversely mounted on the sub-mount on which the circuit is formed. However, the significant deficiencies of the conventional technique consist in that the adoption of these manufacturing methods makes the manufacture time-consuming and inefficient and also increases manufacturing cost.

In view of the aforementioned conventional deficiencies, the present inventor makes a diligent study to provide a high-efficiency matrix-type LED device capable of simplifying manufacturing procedure and saving manufacturing cost for the consumer in accordance with the motive of the present invention.

### SUMMARY OF THE INVENTION

It is a main objective of the present invention to disclose a high-efficiency matrix-type LED device capable of simplifying manufacturing procedure effectively and saving manufacturing cost significantly.

It is another objective of the present invention to provide a high-efficiency matrix-type LED device applicable to AC/DC power.

It is a further objective of the present invention to provide a high-efficiency matrix-type LED device with good abilities to dissipate heat and to resist electrostatic discharge (ESD).

In order to achieve the aforementioned objectives, a high-efficiency matrix-type LED device comprises an epitaxial wafer on which a plurality of independently insulated LEDs are formed by a method of manufacturing integrated circuits; and a conducting line mounted on each one of the LEDs by an evaporation method for forming a large-sized matrix-type LED unit capable of increasing brightness, simplifying manufacturing procedure, and saving manufacturing cost effectively. In addition, a sub-mount having a two-way Zener diode embedded therein is applied to the matrix-type LED unit. By mounting the matrix-type LED unit on the sub-mount, the two-way Zener diode can protect the LEDs against damage from ESD so as to increase lifetime of LEDs.

The aforementioned aspects and advantages of the present invention will be readily clarified in the description of the preferred embodiments and the enclosed drawings of the present invention.

### BRIEF DESCRIPTION OF THE DRAWINGS

FIG. 1 is a three-dimensional view showing the matrix-type LED unit of the present invention.

FIG. 2 is a schematic, cross-sectional view showing the matrix-type LED unit of the present invention.

FIG. 3 is a schematic, cross-sectional view showing the sub-mount of the present invention.

FIG. 4 is a top view of FIG. 3.

FIG. 5 is a schematic, cross-sectional view showing that the matrix-type LED unit is mounted on the sub-mount.

FIG. 6 is an equivalent circuit diagram showing that the DC power is applied to the present invention.

FIG. 7 is an equivalent circuit diagram showing that the AC power is applied to the present invention.

### DETAILED DESCRIPTION OF THE PREFERRED EMBODIMENT

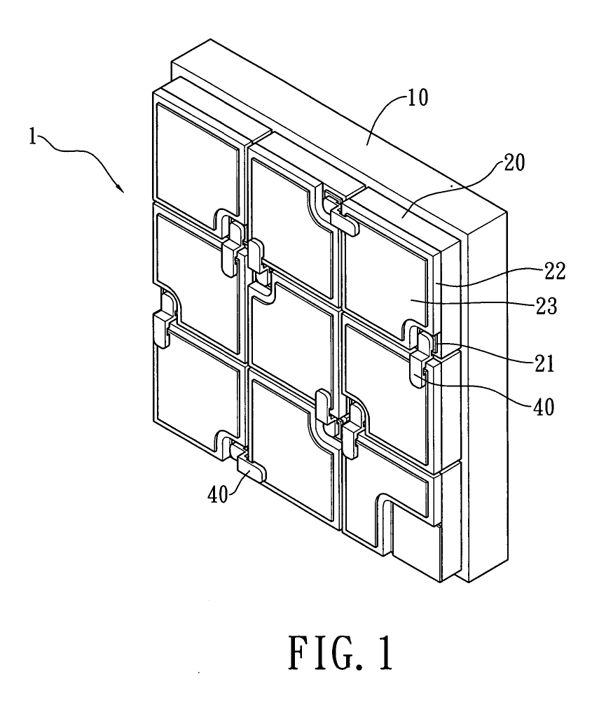

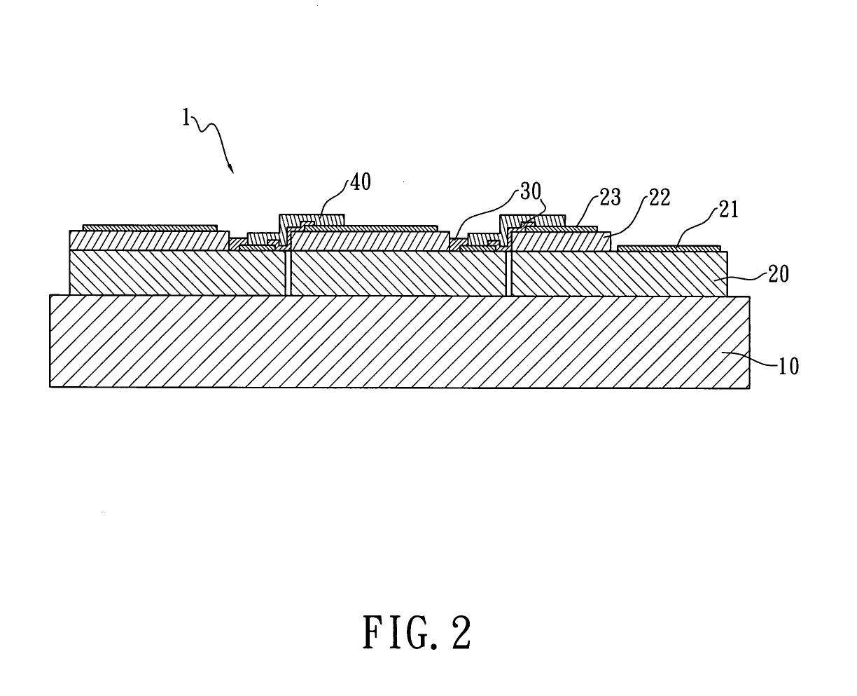

The present invention relates to III-V semiconductor compounds consisting of elements from groups III (e.g., Al, Ga, or In) and V (e.g., N, P, or As) of the periodic table. Referring to FIG. 1 and FIG. 2, a matrix-type LED unit 1 is shown, a plurality of LEDs are formed on a transparent epitaxial wafer 10. These LEDs are arranged in a square matrix (3×3, 4×4, 5×5, etc). A 3×3 matrix is adopted in this preferred embodiment. Each one of the LEDs is composed of a N-type semiconductor layer 20, a N-type electrode 21, a P-type semiconductor layer 22, and a P-type electrode 23. An insulating treatment is performed on the LEDs before the adoption of the metal evaporation method for forming a plurality of conducting lines 40 on the LEDs such that an insulating layer 30 is formed on the outside of every LED. This insulating layer 30 is made of a material selected from SiOₓ, SiNₓ, Al₂O₃, TiN, etc. As a result, every LED is independent from one another. Thereafter, the conducting line 40 is formed on this independent LED by the metal evaporation method. The conducting line 40 is made of a material selected from Au, Al, Ti, Pt, Cr, Ni, W, Cu, or any combination thereof. These LEDs can be connected to the conducting lines 40 in parallel, series or a mixture of parallel and series. As a result, the manufacture of the matrix-type LED unit 1 is completed.

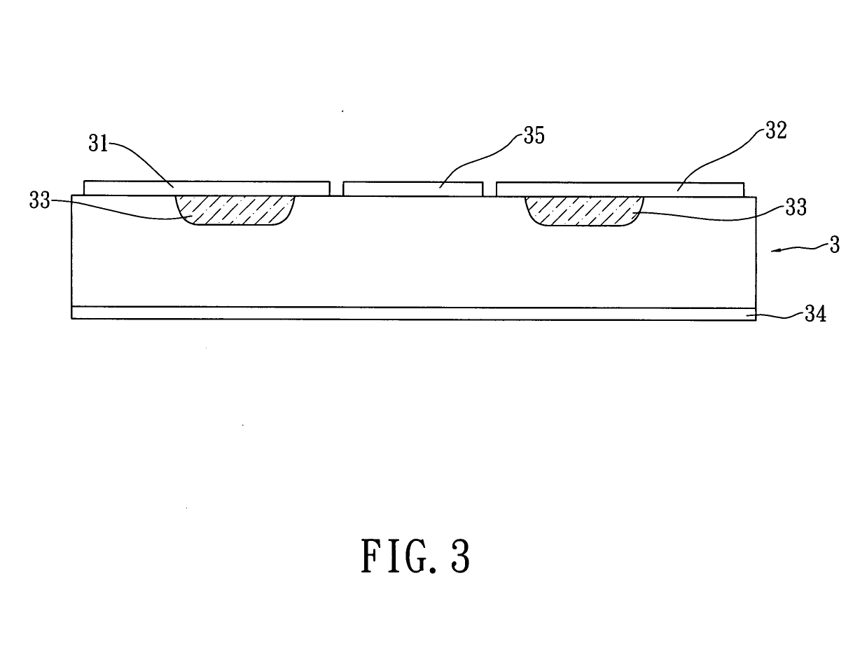

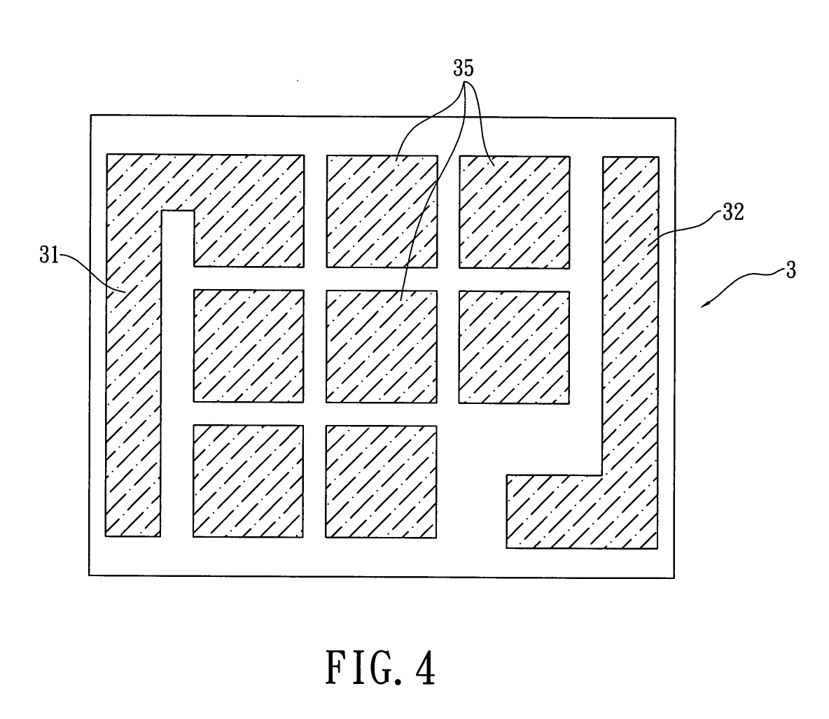

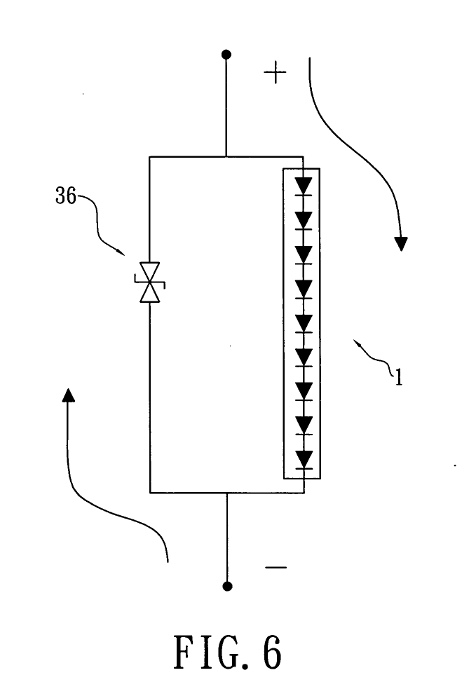

Referring to FIG. 3 and FIG. 4, a sub-mount 3 inside which a two-way Zener diode 36 (shown in FIG. 6) is embedded is applied to the matrix-type LED unit 1. The sub-mount 3 is made of P-type or N-type semiconductor (silicon) material. In addition, a first electrode 31 and a second electrode 32 of the two-way Zener diode 36 are mounted on the sub-mount 3. Besides, active regions 33 of the two-way Zener diode 36 are formed by an ion implantation method or diffusion method. Besides, a heat-conducting metal 34 and a heat-conducting metal 35 are mounted on the top and the bottom of the sub-mount 3 respectively.

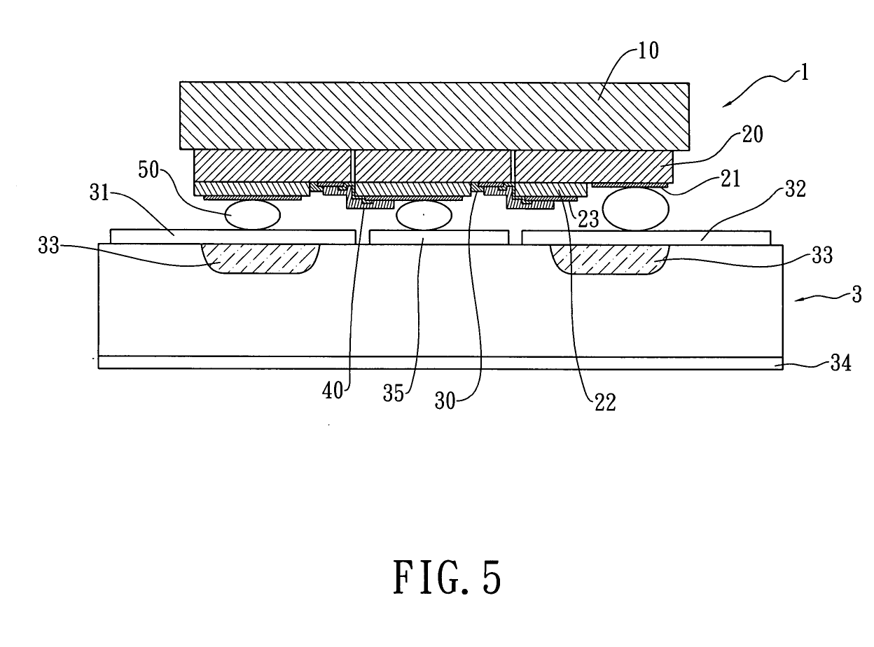

As shown in FIG. 5, when mounting the matrix-type LED unit 1 on the sub-mount 3, the matrix-type LED unit 1 is reversed upside down such that the conducting lines 40 are located to face downward. A plurality of metal protrusions 50 made of Au, AuSn, Sn, Al, or any combination thereof are adopted as contacts. In addition, an ultrasonic connection method is applied so as to inversely mount the matrix-type LED unit 1 on the sub-mount 3. As a result, there is no more a need to reverse every LED individually and mount it on the sub-mount 3 on which the circuit is formed. Besides, there is neither a need to mount every single LED on the sub-mount and then perform the wire-bonding process on every single LED on the sub-mount. Accordingly, the present invention simplifies manufacturing procedure and saves manufacturing cost effectively.

In addition, by inversely mounting the matrix-type LED unit 1 on the sub-mount 3, the heat generated by the LEDs of the matrix-type LED unit 1 can be effectively delivered to the package's frame from top to bottom through the heat-conducting metals 34 and 35. In the conventional structure, the heat generated by operation causes the operation voltage unstable. However, in the present invention, because of having good ability to dissipate heat, the occurrence of unstable operation voltage is prevented, and the light can pass through the transparent epitaxial wafer 10 of the inversely mounted matrix-type LED unit 1 without being blocked by the front electrodes such that the light-emitting efficacy is increased. Moreover, the direct current is applied to the matrix-type LED unit 1 mounted on the sub-mount 3. Referring to the equivalent circuit diagram shown in FIG. 6, the matrix-type LED unit 1 is connected to the two-way Zener diode 36 in parallel. Because the two-way Zener diode 36 has two-way Zener breakdown voltage, it can protect the LEDs of the matrix-type LED unit 1 from being damaged by ESD.

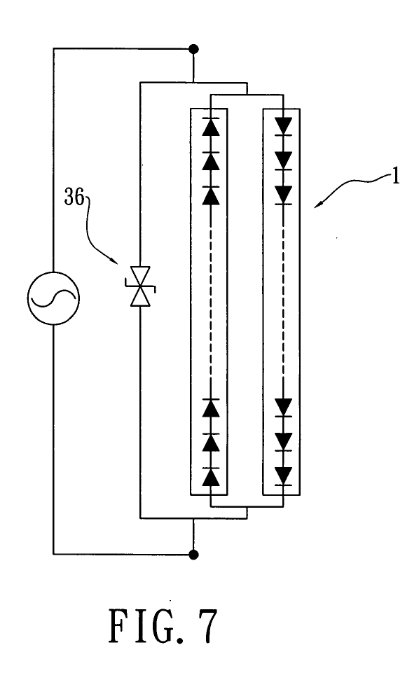

At 20 mA DC, the operation voltage applied to the general LED is ranged from 2 V to 4 V so the required voltage of the series connected 25 LEDs can reach about 100 V. Therefore, as shown in FIG. 7, if two 5×5 matrix-type LED units 1 are inversely parallel connected and further parallel connected to the sub-mount 3, then the 100V AC voltage can be applied for triggering them. After actuation, these parallel-connected matrix-type LED units 1 can emit light alternatively. As a result, the adoption of transformer circuit can be omitted for saving cost.

From the mention above, it is apparent that the structure of the present invention provides the following advantages, in which:

1. Several LEDs mounted on the epitaxial wafer are arranged in a square matrix and the conducting lines are formed on the LEDs by the metal evaporation method so as to form the matrix-type LED unit, thereby simplifying manufacturing procedure and saving manufacturing cost effectively.

2. The sub-mount has a two-way Zener diode embedded therein for protecting the LEDs of the matrix-type LED unit from being damaged by the ESD.

3. The heat generated by the operation of the LEDs can be dispersed via the sub-mount so as to prevent the stability of the operation voltage from being affected.

In summary, the high-efficiency matrix-type LED device of the present invention satisfies patentability. In addition, it simplifies manufacturing procedure and saves manufacturing cost effectively. Accordingly, it is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A matrix-type LED device comprising:
an epitaxial wafer on which a plurality of independently insulated LEDs are formed by a method of manufacturing integrated circuits; and
a conducting line mounted on each one of the LEDs by an metal evaporation method, wherein the conducting line is connected to the LED in parallel or series so as to form a matrix-type LED unit for simplifying manufacturing procedure and saving manufacturing cost effectively.

2. The matrix-type LED device of claim 1, wherein a sub-mount is applied to the matrix-type LED unit.

3. The matrix-type LED device of claim 2, wherein a plurality of stud bumps are adopted as contacts and the matrix-type LED unit is inversely mounted on the sub-mount by an ultrasonic connection method.

4. The matrix-type LED device of claim 2, wherein the sub-mount is made of silicon, AlN, or BeO, a two-way Zener diode suitable applicable to AC (alternating current) power is mounted inside the sub-mount to protect the LEDs from being damaged by ESD, and two heat-conducting metals are mounted on the top and the bottom of the sub-mount respectively.

5. The matrix-type LED device of claim 4, wherein the heat-conducting metals have high heat-conducting coefficient, and the heat-conducting metals are made of Au, Al, Ti, Pt, Cr, Ni, W, Cu, or any combination thereof.

6. The matrix-type LED device of claim 4, wherein the two-way Zener diode mounted in the sub-mount is formed by an ion implantation method or an ion diffusion method.

7. The matrix-type LED device of claim 1, wherein each one of the LEDs is insulated by an insulating layer made of a material selected from SiOₓ, SiNₓ, Al₂O₃, TiN, or any combination thereof.

8. The matrix-type LED device of claim 1, wherein the conducting lines are formed by the metal evaporation method and the conducting lines are made of a material selected from Au, Al, Ti, Pt, Cr, Ni; W, Cu, or any combination thereof.

9. The matrix-type LED device of claim 1, wherein each one of the LEDs has a P-type electrode and a N-type electrode, and the P-type and N-type electrodes are made of high heat-conducting and low-resistivity metals selected from Au, Al, Ti, Pt, Cr, Ni, W, Cu, or any combination thereof.

10. The matrix-type LED device of claim 1, wherein the LEDs are P-type and N-type III-V semiconductor compounds.

11. The matrix-type LED device of claim 1, wherein the epitaxial wafer is transparent.
